(19) United States
(12) Patent Application Publication
(10) Pub. No.: US 2016/0071822 A1
(43) Pub. Date: Mar. 10, 2016

(54) OPTIMIZING POWER DISTRIBUTION FROM A POWER SOURCE THROUGH A C4 SOLDER BALL GRID INTERCONNECTED THROUGH SILICON VIAS IN INTERMEDIATE INTEGRATED CIRCUIT CHIP CONNECTED TO CIRCUITRY IN AN UPPER INTEGRATED CIRCUIT CHIP THROUGH A GRID OF MICRO uC4 SOLDER BALLS

(71) Applicant: International Business Machines Corporation, Armonnk, NY (US)

(72) Inventors: Gerald K. Bartley, Rochester, MN (US); Wiren Dale Becker, Hyde Park, NY (US); Andreas Huber, Boebligen (DE); Tingdong Zhou, Austin, TX (US)

(21) Appl. No.: 14/479,745

(22) Filed: Sep. 8, 2014

(51) Int. Cl. H01L 25/065; H01L 25/00

(52) U.S. Cl. CPC H01L 25/0657; H01L 25/50; H01L 2225/06513; H01L 2225/06541; H01L 2225/06517

(57) ABSTRACT

In an integrated chip stack arrangement, wherein power is provided to an upper integrated chip, including a processor core with a grid arrangement of cells connected to a power supply in a substrate by a conventional C4 solder ball array on the substrate connected through TSVs in an intermediate integrated circuit chip, it has been recognized that for maximum current efficiency and minimum electro migration the vias should not be directly coincident with the micro C4 solder balls connecting the upper chip with the intermediate chip.

### TECHNICAL FIELD

The present invention relates to uC4 solder ball connected integrated circuit chips, particularly to stacked integrated circuit chips using micro uC4 ball arrays to connect chips in package stacks.

### BACKGROUND OF RELATED ART

Microelectronic components are continually being miniaturized into area integrated circuit chip arrays. The present technology has advanced to the point that three dimensional chip stacks are used in which a power supply provided from the substrate through conventional C4 solder ball arrays, then Through Silicon Vias (TSVs) in an intermediate integrated chip from which the power is transmitted through smaller, i.e. micro uC4 solder ball arrays, to power up integrated circuit memory and logic areas or cells.

The uC4 interface uses smaller C4 solder balls. It also has a high percentage of tin material to improve the reliability of the interface. This exposes the interface to high electro-migration (EM) concern. The uC4 ball current limit is small; about 25 mA is the maximum reliable uC4 current for uC4 balls with a diameter of about 30 urn. This limits how much power can be delivered to the top chip. With such micro C4 interconnectors the current flow through the individual solder balls is different from location to location. Some micro C4 solder balls will carry a lot more current than others that are connected to low power density areas in the upper integrated circuit chip. These conditions are in part due to uneven power density distribution from upper chip area to area. Also, the path resistances from the voltage regulation controlled power source on the substrate are different between micro C4 paths through solder balls that have different resistances.

It would be desirable to minimize the effects of the electro migration upon the efficiency of powering-up the memory and logic areas in the upper integrated circuit chip.

### SUMMARY OF THE PRESENT INVENTION

The present invention relates to an integrated circuit package in which a substrate having conductive interconnectors is connected through a first grid array of C4 solder balls to the first integrated circuit chip including TSVs mounted on said grid array of C4 solder balls. The chip has a conductive connector grid pattern coincident with the grid array of C4 solder balls by which the integrated circuit chip is connected to the conductive interconnectors in the substrate. A second grid array of C4 solder balls on the upper surface of the integrated circuit chip is connected to conductive interconnectors on the upper surface of this first integrated circuit chip, and a second integrated circuit chip mounted on the second grid array of C4 solder balls, wherein the second grid array of C4 solder balls connects conductive connectors in the second chip to the conductive interconnectors on said upper surface. The C4 solder balls in the second grid array are offset so as not to horizontally coincide with TSVs in the first integrated circuit chip. The C4 solder balls in said second array are smaller than the C4 solder balls in said first array.

In accordance with an aspect of the invention, there is a power source on the substrate connected to the second integrated circuit chip through the second grid array of C4 solder balls, and the TSVs in the first integrated circuit chip, and the second integrated circuit chip includes a core area, and connection through said TSVs to provide power to said core area.

This core area includes read only memory (RAM) and the power is provided to said RAM. Also included in the core area is core logic integrated circuitry and the power is provided to said core logic integrated circuitry.

In accordance with another aspect of the invention, the core area is a rectilinear area comprising an array of rectilinear cells mounted on coincident rectilinear cells of C4 solder balls in said second grid array, wherein each cell of C4 solder balls is coincident with a corresponding TSV in the first integrated circuit chip, but the C4 solder balls in each cell are offset so as to not coincide with said corresponding TSV.

In accordance with a more particular aspect of the invention, the core area in the second integrated circuit chip is a rectilinear area comprised of an array of rectilinear cells mounted on coincident rectilinear cells of C4 solder balls in the second grid array, wherein each cell of C4 solder balls is coincident with a central corresponding TSV in the first integrated circuit chip and the C4 solder balls in each cell are formed in a regular column/row pattern, but with a missing central C4 ball over the TSV.

In another like aspect, the core area in said second integrated circuit chip is a rectilinear area comprising an array of rectilinear cells mounted on coincident rectilinear cells of C4 solder balls in the second grid array, wherein each cell of C4 solder balls is coincident with a central corresponding TSV in the first integrated circuit chip, and the C4 solder balls in each cell are formed in a regular column and row pattern, but with the row over the TSV being offset so that no C4 solder ball coincides with the TSV.

### BRIEF DESCRIPTION OF THE DRAWINGS

The present invention will be better understood and its numerous objects and advantages will become more apparent to those skilled in the art by reference to the following drawings, in conjunction with the accompanying specification, in which:

FIG. 1 is a breakout section of a portion of an integrated circuit package wherein power is provided from a substrate supply through conventional C4 balls, then through TSVs in an intermediate chip connected to a micro C4 ball array to an upper integrated circuit processor chip in accordance with the present invention;

FIG. 2 is an enlarged section like that of FIG. 1 of an individual cell in a grid array according to the prior art;

FIG. 3 is an enlarged view like that of FIG. 2 except that it is structured in accordance with one embodiment of the present invention;

FIG. 4 is a sectional view like that of FIG. 3 but showing another aspect of the present invention;

FIG. 5 is a top view of a section of a core area in the upper integrated circuit chip illustrating the normal relationship of its micro solder balls with underlying TSVs;

FIG. 6 is an enlarged section of the cell array in FIG. 5 but illustrating the embodiment of the present invention shown in the side sectional view of FIG. 3; and

FIG. 7 is an enlarged section of the cell array in FIG. 5 but illustrating the embodiment of the present invention shown in the side sectional view of FIG. 4.

### DETAILED DESCRIPTION OF THE PREFERRED EMBODIMENT

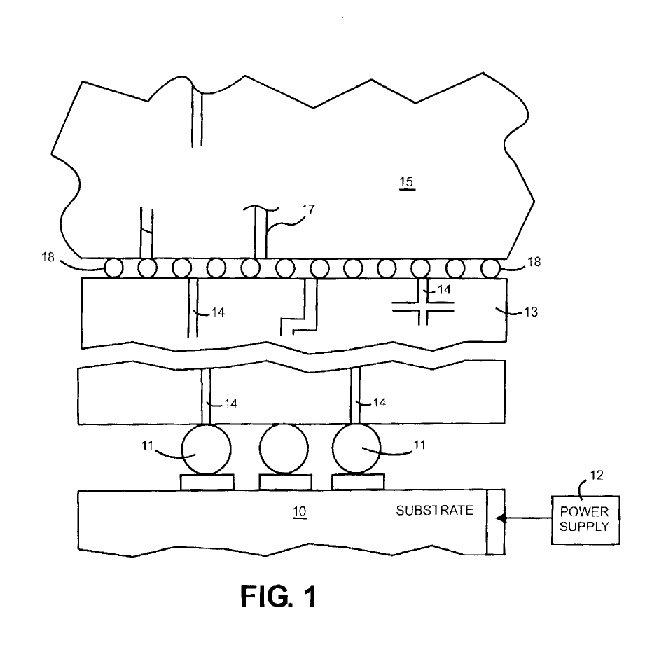

With reference to FIG. 1 there is shown a breakout section of a portion of an integrated circuit package wherein power is provided from a substrate supply through conventional C4 balls, then through TSVs in an intermediate chip connected to a micro C4 ball array to an upper integrated circuit processor chip. A power supply 12 is provided through appropriate interconnectors in substrate 10 and then through conventionally sized C4 solder balls 11 in turn connected to TSVs 14 in first chip 13. These TSVs 14 conduct, among other current factors, power to units in upper chip 15. The connection between chips 13 and 15 is through an array of micro uC4 solder balls 18 that connect the TSVs 14 to appropriate elements in upper chip 15, which has its own vias 17, as well as other conventional metallization layers. Because the uC4 interface uses smaller C4 balls and has a high percentage of tin material to improve the reliability of the interface, that interface is subject to high electro-migration (EM) concerns. The uC4 ball current limit is small. It is around 25 mA as a maximum reliable uC4 current for uC4 ball with diameter of about 30 um. This limits how much current can be delivered to the top chip.

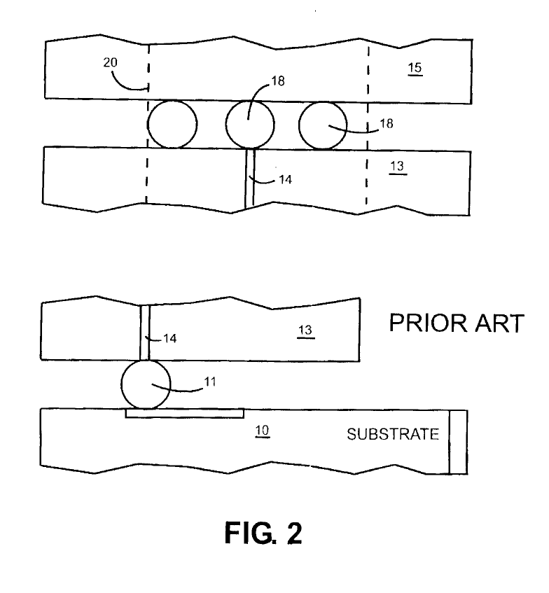

In order to understand the implementations of the present invention to minimize electro-migration and, thus, optimize the delivery current efficiency; reference is made to FIG. 2 that represents an enlarged section like that of FIG. 1 of an individual cell in a grid array according to the prior art. Current from substrate 10 is connected through conventional C4 solder ball 11 and via 14 through first chip 13 and connecting micro solder balls 18 to cells 20 in integrated circuit chip 15. It is to be noted that micro solder ball 18, which is part of array cell 20, requiring power for the memory or chip logic function performed by cell 20. This will hereinafter be described in greater detail. It is to be noted that TSV 14 coincides with solder ball 18. It appears to be customary that one of the micro solder balls 18 in a cell array will coincide with a TSV 14. The present invention has found that if the coincidence of the micro C4 solder ball and the vias in the TSVs are off-set so as to eliminate or at least minimize the coincidence of micro solder balls and vias, the electro migration problem described hereinabove is minimized.

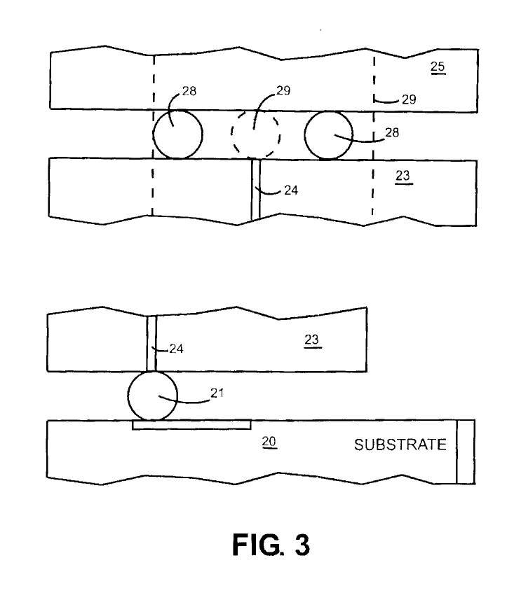

This is shown with respect to FIG. 3 that is an enlarged view like that of FIG. 2, except that it is structured in accordance with one embodiment of the present invention. In the FIG. 3 embodiment, power is provided from substrate 20 through solder ball 21 and vias 24 in the first chip 23 to array cell 29 through micro solder ball 28. However, it is noted that the solder ball array is offset with respect to array cell 29 so that the micro C4 ball that would usually coincide with vias 24 is missing 27.

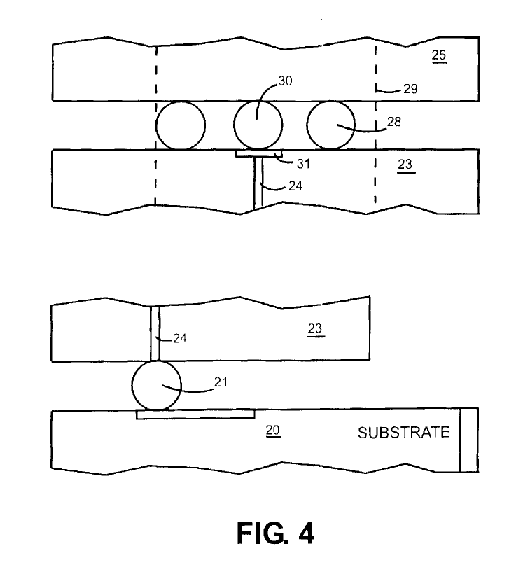

FIG. 4 shows another embodiment of the present invention with respect to offset micro C4 solder ball. It is a sectional view like that of FIG. 3 but showing another aspect of the present invention. Like the previous embodiment, in FIG. 4 it is noted that micro solder ball 30 is offset from 24 but may be connected to 24 from appropriate metallization 31 on the upper surface of chip 23.

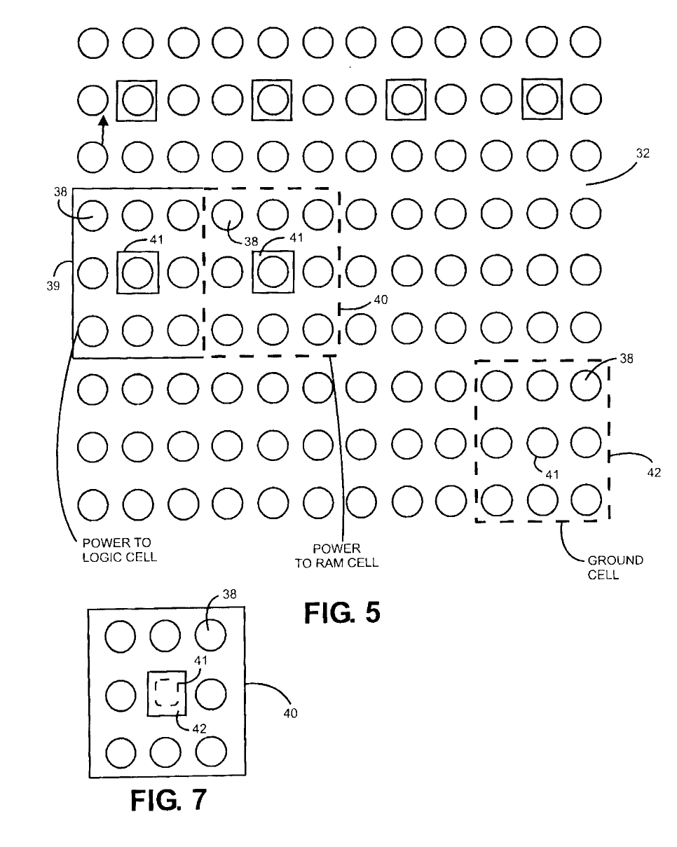

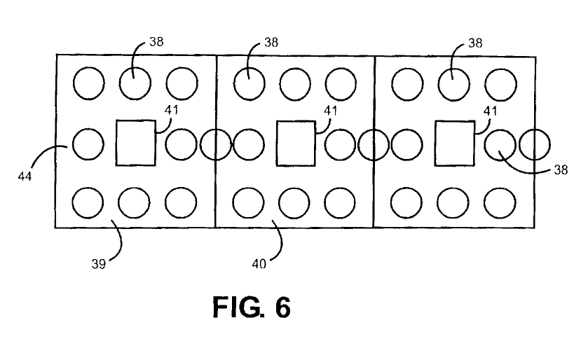

FIG. 5 is a top view of a section of a core area in the upper integrated circuit chip illustrating the normal relationship of its micro solder balls with underlying TSVs. The section of 32 shown illustrates a micro C4 ball grid that coincides with cells in the core area of a functional integrated circuit chip arranged in cell units such as, 39, 40 and 42. For example, cell 42 is connected to ground. While cells 39 and 40 are respectively logic cells and RAM memory cells to be supplied with power in the integrated circuit stack package. The conventional power supply to a cell is provided by a regular micro C4 ball arrangement of a solder ball square array, e.g. 9 solder balls arranged in uniform columns and rows as shown in cells 39, 40 and 42. A conventional arrangement would be one TSV 41 centrally located in the cell so that it coincides with the central ball in the array. With such an arrangement there will be current crowding with respect to the micro C4 solder ball coincident with the central TSV. This condition significantly contributes to unwanted electro-migration. Accordingly, the implementation of the present invention for the reduction of electro-migration that was previously described with respect to FIGS. 3 and 4 is shown in top view with respect to FIGS. 6 and 7. In FIG. 6, for example, the solder balls in the central row of the chip array 44 are offset by ½ space so that the vias 41 will be in between the solder balls 38 as previously described with respect to FIG. 4.

Similarly in the view of FIG. 7, as previously described with respect to FIG. 3, the central ball 42 that would normally coincide with vias 41 is removed and the balls 38 are appropriately connected by metallization (not shown).

Although certain preferred embodiments have been shown and described, it will be understood that many changes and modifications may be made therein without departing from the scope and intent of the appended claims.

What is claimed is:

1. An integrated circuit package comprising:
a substrate having conductive interconnectors;
a first grid array of C4 solder balls on said substrate respectively connected to the substrate interconnectors;
a first integrated circuit chip including TSVs (Through Silicon Vias) mounted on said grid array of C4 solder balls, said chip having a conductive connector grid pattern coincident with said grid array of C4 solder balls wherein said integrated circuit is connected to said conductive interconnectors in said substrate;
a second grid array of C4 solder balls on the upper surface of said integrated circuit chip connected to conductive interconnectors on said upper surface of said first integrated circuit chip; and
a second integrated circuit chip mounted on said second grid array of C4 solder balls, wherein said second grid array of C4 solder balls connects conductive connectors in said second chip to said conductive interconnectors on said upper surface, wherein said C4 solder balls in said second grid array are offset so as not to horizontally coincide with TSVs in said first integrated circuit chip.

2. The integrated circuit package of claim 1, further including a power source on said substrate connected to said second integrated circuit chip through said second grid array of C4 solder balls, and said TSVs in said first integrated circuit chip.

3. The integrated circuit package of claim 2, wherein the C4 solder balls in said second array are smaller than the C4 solder balls in said first array.

4. The integrated circuit package of claim 2, wherein said second integrated circuit chip includes a core area and connection through said TSVs to provide power to said core area.

5. The integrated circuit package of claim 4, wherein a core area includes RAM and said power is provided to said RAM.

6. The integrated circuit package of claim 4, wherein a core area includes core logic integrated circuitry and said power is provided to said core logic integrated circuitry.

7. The integrated circuit package of claim 4, wherein:
said core area in said second integrated circuit chip is a rectilinear area comprising an array of rectilinear cells mounted on coincident rectilinear cells of C4 solder balls in said second grid array, wherein each cell of C4 solder balls is coincident with a corresponding TSV in the first integrated circuit chip, but the C4 solder balls in each cell are offset so as not to coincide with said corresponding TSV.

8. The integrated circuit package of claim 6, wherein:
said core area in said second integrated circuit chip is a rectilinear area comprising an array of rectilinear cells mounted on coincident rectilinear cells of C4 solder balls in said second grid array, wherein
each cell of C4 solder balls is coincident with a central corresponding TSV in the first integrated circuit chip, and
the C4 solder balls in each cell are formed in a regular column/row pattern, but with a missing central C4 ball over the TSV.

9. The integrated circuit package of claim 7, wherein:
said core area in said second integrated circuit chip is a rectilinear area comprising an array of rectilinear cells mounted on coincident rectilinear cells of C4 solder balls in said second grid array, wherein
each cell of C4 solder balls is coincident with a central corresponding TSV in the first integrated circuit chip, and
the C4 solder balls in each cell are formed in a regular column and row pattern, but with the row over the TSV being offset so that no C4 solder ball coincides with said TSV.

10. The integrated circuit package of claim 7, wherein:
said TSV coincident with a cell of C4 solder balls provides said conductive connection through said coincident TSV to provide power to RAM in the core area.

11. The integrated circuit package of claim 7, wherein:
said TSV coincident with a cell of C4 solder balls provides said conductive connection through said coincident TSV to provide power to logic circuitry in the core area.

12. A method for making an integrated circuit package comprising:
forming a first grid array of C4 solder balls on a substrate having conductive interconnectors, said solder balls being respectively connected to the substrate interconnectors;
mounting a first integrated circuit chip including TSVs (Through Silicon Vias) on said grid array of C4 solder balls, said chip having a conductive connector grid pattern coincident with said grid array of C4 solder balls wherein said integrated circuit is connected to said conductive interconnectors in said substrate;
forming a second grid array of C4 solder balls on the upper surface of said integrated circuit chip connected to conductive interconnectors on said upper surface of said first integrated circuit chip; and
mounting a second integrated circuit chip mounted on said second grid array of C4 solder balls, wherein said second grid array of C4 solder balls connects conductive connectors in said second chip to said conductive interconnectors on said upper surface, wherein
said C4 solder balls in said second grid array are offset so as not to horizontally coincide with TSVs in said first integrated circuit chip.

13. The method of claim 12, further including connecting a power source on said substrate to said second integrated circuit chip through said second grid array of C4 solder balls and said TSVs in said first integrated circuit chip.

14. The method of claim 13, wherein the C4 solder balls in said second array are smaller than the C4 solder balls in said first array.

15. The method of claim 13, wherein said second integrated circuit chip includes a core area and connection is provided through said TSVs to power said core area.

16. The method of claim 15, wherein a core area includes RAM and said power is provided to said RAM.

17. The method of claim 15, wherein a core area includes core logic integrated circuitry and said power is provided to said core logic integrated circuitry.

18. The method of claim 15, wherein:
said core area in said second integrated circuit chip is a rectilinear area comprising an array of rectilinear cells mounted on coincident rectilinear cells of C4 solder balls in said second grid array, wherein
each cell of C4 solder balls is coincident with a corresponding TSV in the first integrated circuit chip, and
offsetting the C4 solder balls in each cell so as not to coincide with said corresponding TSV.

19. The method of claim 17, wherein:
said core area in said second integrated circuit chip is a rectilinear area comprising an array of rectilinear cells mounted on coincident rectilinear cells of C4 solder balls in said second grid array, wherein
each cell of C4 solder balls is coincident with a central corresponding TSV in the first integrated circuit chip, and
forming the C4 solder balls in each cell in a regular column and row pattern, but with a missing central C4 solder ball over the TSV.

20. The method of claim 18, wherein:
said core area in said second integrated circuit chip is a rectilinear area comprising an array of rectilinear cells mounted on coincident rectilinear cells of C4 solder balls in said second grid array, wherein
each cell of C4 solder balls is coincident with a central corresponding TSV in the first integrated circuit chip, and
the C4 solder balls in each cell are formed in a regular column and row pattern, but with the row over the TSV being offset so that no C4 solder ball coincides with said TSV.

21. The method of claim 19, wherein said TSV coincident with a cell of C4 solder balls provides said conductive connection through said coincident TSV to provide power to RAM in the core area.

22. The method of claim 18, wherein said TSV coincident with a cell of C4 solder balls provides said conductive connection through said coincident TSV to provide power to logic in the core area.
